(19) United States
(12) Patent Application Publication
(10) Pub. No.: US 2013/0106433 A1
(43) Pub. Date: May 2, 2013

(54) RESETTABLE FUSED JUMPER LEAD

(71) Applicant: Randell Lee Wilferd, Pleasant Hill, CA (US)

(72) Inventor: Randell Lee Wilferd, Pleasant Hill, CA (US)

(21) Appl. No.: 13/661,197

(22) Filed: Oct. 26, 2012

Related U.S. Application Data
(60) Provisional application No. 61/551,726, filed on Oct. 26, 2011.

(51) Int. Cl. G01R 31/00

(52) U.S. Cl. CPC G01R 31/006
USPC 324/503

(57) ABSTRACT

An automotive circuit tester consisting of a jumper wire having a spring loaded clip at one side and voltage probe at the other incorporates a fuse holder utilized for the housing of an electric current resectable fuse.

### BACKGROUND

Automotive electrical systems mainly consist of switches, relays, microprocessors, fuses, circuit breakers and current transfer wire, all of which together forms an automotive electrical circuit. There are many individual current rated circuits within the structure with all either vital to the operation or accessory function of the vehicle.

The role of a fuse is to protect the circuit from electrical overload. All fuses are amperage rated which if exceeded, causes the fuse to open or blow therefore stopping excessive current flow beyond the fuse point.

Within an automotive circuit, many failure points exist which increases the overall time required for a technician to diagnose and isolate the problem. An open or blown fuse now becomes a by-product of the failure as it is designed to fail in order to protect the circuit and whereas the blown fuse may not necessarily be the actual cause of the failure.

When a technician diagnoses a failed circuit, his first step is always to replace the blown fuse allowing the circuit once again to be whole for diagnostics. However this fuse replacement is typically at a cost to the owner of the vehicle and several may have to be used prior to finding and correcting the electrical issue.

### SUMMARY OF THE INVENTION:

This present invention presents an electrical circuit testing method and system consisting of a wire having at least one spring loaded connecting clip and a voltage probe.

A fuse housing incorporated within the wire accepts a replaceable and resettable fuse based on the circuits current rating.

This configuration allows jumping connection between the power source and any way point within a failed circuit until the failure location has been isolated.

When electrical diagnostics are being performed, the present invention provides an option to a technician of not having to replace the OEM fuse several times during prior to isolating the problems. The change of location from the vehicle's fuse box to the jumper wire provides easy access for the technician for resetting the fuse each time the circuit opens.

All automotive circuits vary in current load requirement and therefore the present invention allows the replacement of the resettable fuse based on the current requirement of the circuit. As an example, an auto stereo system may only require an amperage rating of ten but whereas an air conditioning system may have a rating of 30 amps.

Commonly when a technician wants to jumper a circuit in order to perform a diagnosis, they sometimes mistakenly make connections between a positive and a negative which may cause additional short circuiting damage to the circuit or to the circuit components. In these cases the present invention having provided a resettable fusing would block excessive current from flowing through the circuit.

### BRIEF DESCRIPTION OF THE DRAWINGS

FIG. 1 illustrates a wire having a spring loaded clip on one end and a voltage probe on the other and incorporated in between the ends is retainment for a resettable fuse.

FIG. 2 illustrates the resettable fuse in the closed position and in relationship to its housing and wire connections.

FIG. 3 illustrates the resettable fuse when in its open position.

Other objects, advantages and novel features of the present invention will become readily apparent from the following drawings and detailed description of the preferred embodiments.

### DETAILED DESCRIPTION OF THE DRAWINGS

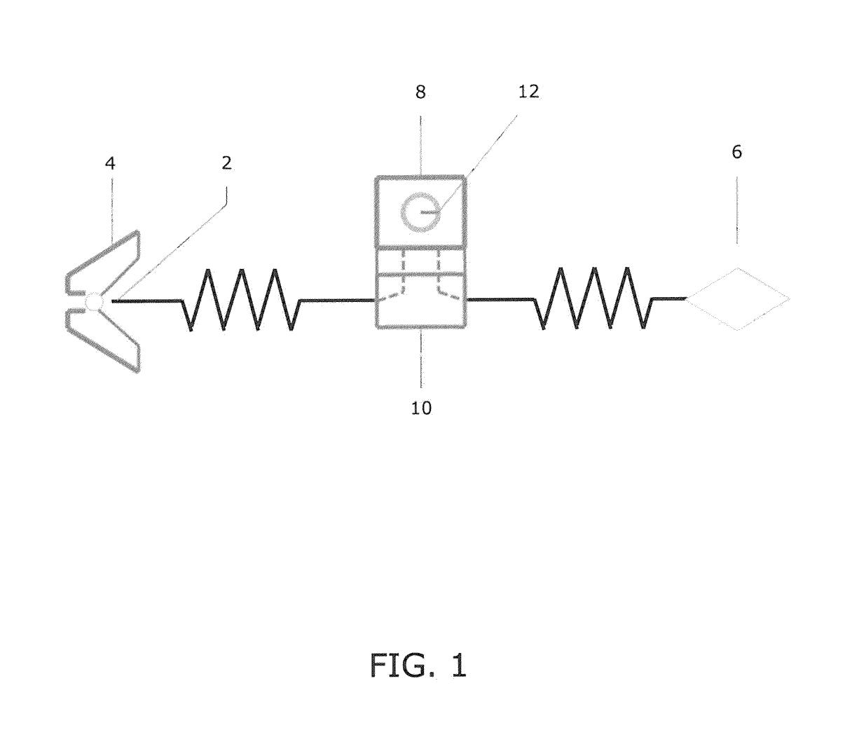

FIG. 1 illustrates explanation of the present invention in a complete form. A heavy gage wire 2 having a high current rating is utilized to transfer current between two points within the circuit. A spring loaded connection clips 4 is located at the end of the wire and provides a retainable connection point to a current source. At the opposite end of the wire is a voltage probe 6 and is used by a technician to jumper the circuit down stream from the spring clip. This secondary connection point requires being of the same polarity as the first connection in order to create a new completed circuit for diagnoses.

The resettable fuse housing 10 makes connections to the wire 2 and is located in between the spring loaded clip 4 and the voltage probe 6. Overload protection is provided for when a properly rated resettable fuse 8 is installed by the technician into the fuse housing 10 prior to his diagnostics. A reset button 12 located on the fuse housing allows the technician to reset the fuse in event of fuse circuit overloads and preventing current flow through the circuit.

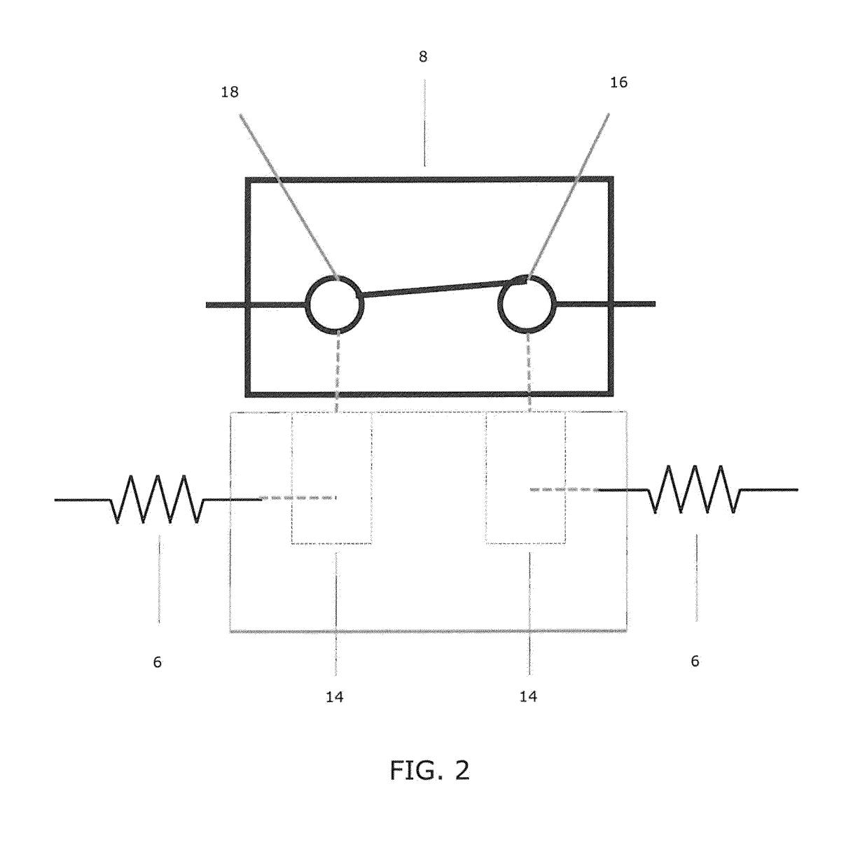

FIG. 2 illustrates the resettable fuse 8 in a closed position and where an internal breaker switch while in the closed position provides current passage through the fuse. Two terminals 14 connect internally to switching pole breaker 16 and 18 which further make connection via the fuse housing to wire 6. If current exceeds the breaker pole capacity, the breaker internal circuit opens stopping current flow through the circuit being diagnosed.

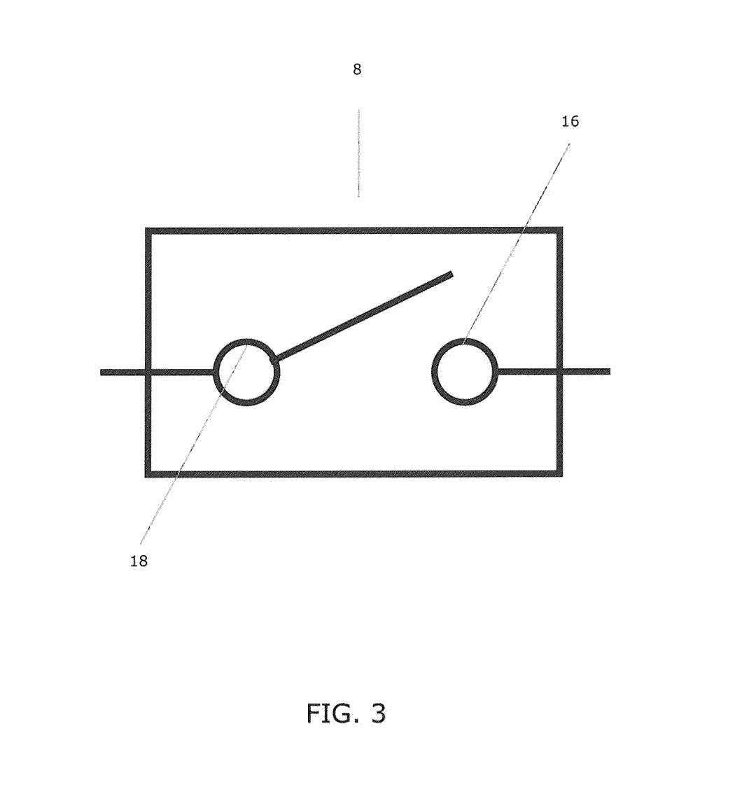

FIG. 3 illustrates resettable fuse 8 internal breaker poles 16 and 18 in an open position. In this position current is not allowed passage through the fuse. This description of the invention is merely exemplary in nature and thus, variations that do not depart from the gist of the invention are intended to be within the scope of the invention. Such variations are not to be regarded as a departure from the spirit and scope of the invention.

What is to be claimed:

1. A heavy gage wire comprised of a spring loaded clip and a voltage probe located at opposite ends is utilized for circuit connection for the purpose of diagnostics.

2. The wire system of claim 1, locates a fuse housing within the wire between the spring clip and voltage probe.

3. The wire system of claim 2 provides housing for a replaceable fuse.

4. The wire system of claim 3 accepts fusing which is resettable if current load exceeds a rated threshold.
